(19) United States
(12) Patent Application Publication
(10) Pub. No.: US 2009/0035895 A1
(43) Pub. Date: Feb. 5, 2009

(54) CHIP PACKAGE AND CHIP PACKAGING PROCESS THEREOF

(75) Inventors: Min-Ik Lee, Kyunggi-Do (KR); Ming-Lu Cui, Kyunggi-Do (KR); Hong-Hyoun Kim, Kyunggi-Do (KR)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/830,188

(22) Filed: Jul. 30, 2007

(51) Int. Cl. H01L 21/00

(52) U.S. Cl. 438/127; 257/E23.117

(57) ABSTRACT

A chip package comprises a substrate, a chip, a conductive layer and a molding compound. The substrate has a carrying surface and at least a ground pad disposed on the carrying surface. The chip has an active surface and a back surface opposite thereto. The chip is bonded to the substrate with the active surface facing towards the carrying surface of the substrate, wherein the ground pad is disposed outside of the chip. The conductive layer covers the chip and a portion of the carrying surface, and electrically connects to the ground pad. The molding compound is disposed on the carrying surface of the substrate and encapsulates the chip and the conductive layer.

### BACKGROUND OF THE INVENTION

1. Field of the Invention

The present invention generally relates to a chip package and a packaging process thereof. More particularly, the present invention relates to a chip package having electromagnetic interference (EMI) shielding function and a packaging process thereof.

2. Description of Related Art

In the manufacturing of integrated circuits, ultimate size of the package is an important issue. As the level of integration and functions of integrated circuits increase, the number of conductive leads required for connections with external circuitry is also increased. Furthermore, as the operating speed of chip goes higher, the electrical interference (EMI) caused by external electromagnetic fields during operation can no longer be ignored.

A known conventional EMI technology is provided for a wire-bonding package, which forms a housing by dipping or dispensing method to securely attach to the package body or directly mounts the housing on the package body by an enforced inserting method such that the housing fits tightly against the package body.

It is noted that the shield i.e. the housing is only disposed on the molding compound i.e. the package body.

### SUMMARY OF THE INVENTION

Accordingly, the present invention is directed to a chip package, which is capable of eliminating the EMI problem with a structure different from the conventional one.

Accordingly, the present invention is directed to a chip package which is capable of eliminating the EMI problem for a flip chip.

The present invention is also directed to a fabricating process of the chip package having EMI shielding ability.

As embodied and broadly described herein, the present invention provides a chip package comprising: a substrate, having a carrying surface and at least a ground pad disposed on the carrying surface; a chip, having an active surface and a back surface opposite thereto, and bonded to the substrate with the active surface facing towards the carrying surface of the substrate, wherein the ground pad is disposed outside of the chip; a conductive layer, covering the chip and a portion of the carrying surface, and electrically connected with the ground pad; and a molding compound, disposed on the carrying surface of the substrate and encapsulating the chip and the conductive layer.

The present invention also provides a chip packaging process, comprising: providing a substrate, having a carrying surface and at least a ground pad disposed on the carrying surface; providing a chip, having an active surface and a back surface opposite thereto; bonding the chip to the substrate by facing the active surface of the chip towards the carrying surface of the substrate, wherein the ground pad is disposed outside of the chip; forming a conductive layer on the chip and a portion of the carrying surface, and electrically connecting the conductive layer with the ground pad; and forming a molding compound on the carrying surface of the substrate and encapsulating the chip and the conductive layer.

According to one aspect of the present invention, the conductive layer can be formed by the following steps: forming a solution on the chip and a portion of the carrying surface by an ink-jet printing method, wherein the solution includes a solvent and a conductive material; and removing the solvent to form the conductive layer with the conductive material remained behind.

According to another aspect of the present invention, the solvent is a volatile solvent, and removing the solvent comprising a heating step to vaporize the solvent of the solution. The volatile solvent can be volatilized, and then the conductive material remained behind forms the conductive layer.

With the present invention, the shield material i.e. the conductive layer can be formed directly on the chip.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 to FIG. 4 illustrate a chip packaging process according to the first embodiment of the present invention in a cross-sectional view.

FIG. 5 to FIG. 8 show top views of FIG. 1 to FIG. 4 respectively.

FIGS. 9 and 10 show flow charts of the chip packaging process according to the first embodiment of the present invention.

FIG. 11 shows a flow chart after a molding compound has been cured in the first embodiment.

FIG. 12 shows a chip package formed by further performing step of FIG. 11 in a cross-sectional view.

FIG. 13 illustrates a chip package according to the second embodiment of the present invention in a cross-sectional view.

FIG. 14 illustrates a modification example of a chip package according to the second embodiment of the present invention in a cross-sectional view.

FIG. 15 illustrates a chip package according to the third embodiment of the present invention in a cross-sectional view.

FIG. 16 illustrates a modification example of a chip package according to the third embodiment of the present invention in a cross-sectional view.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

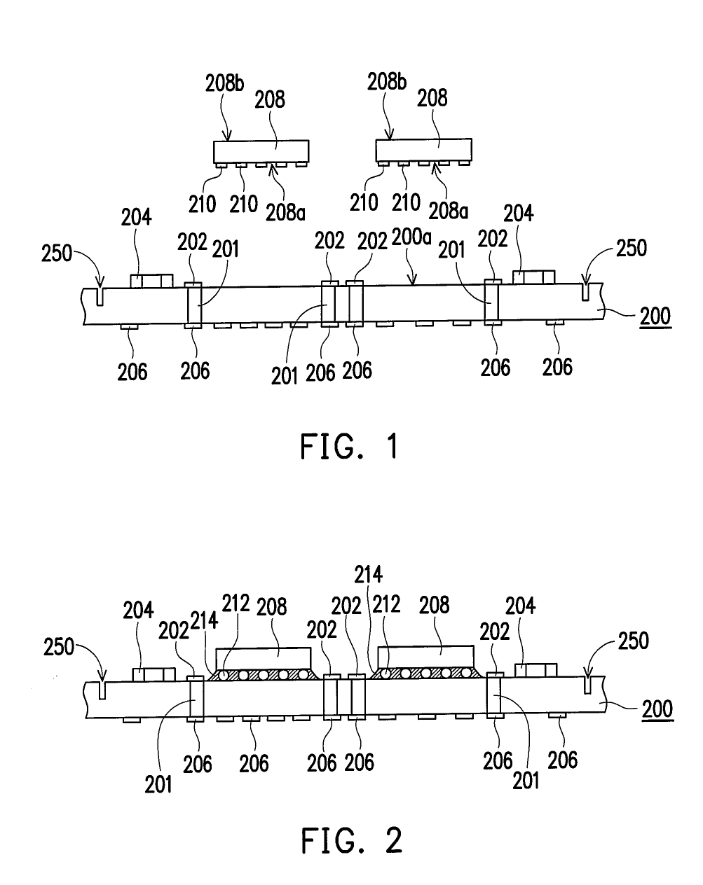

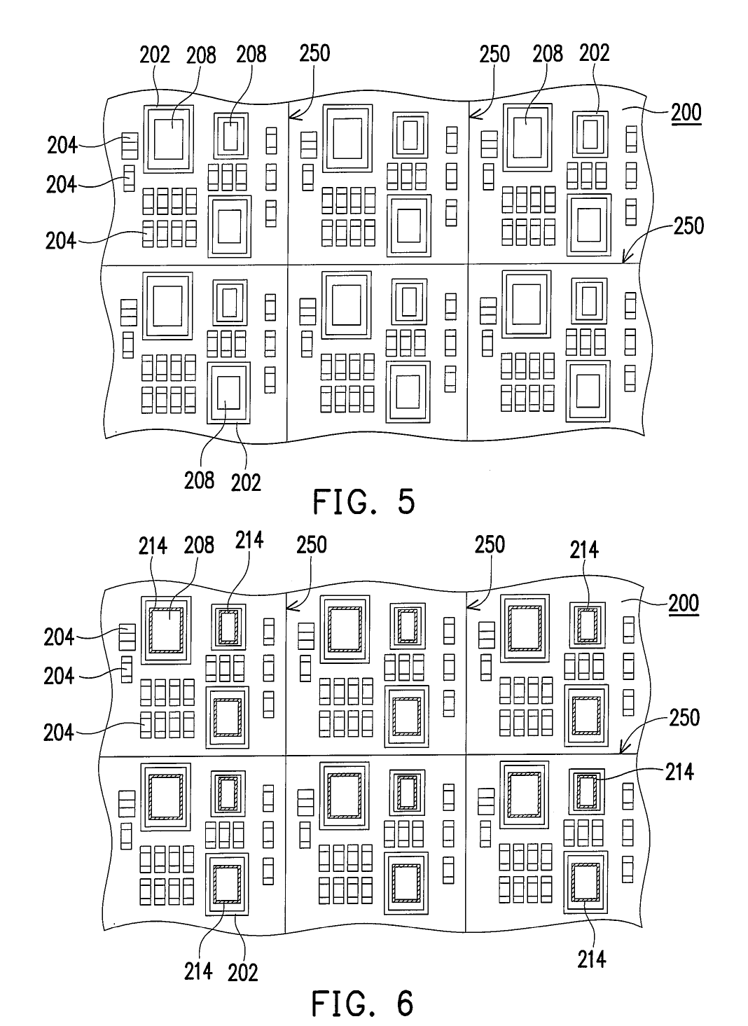

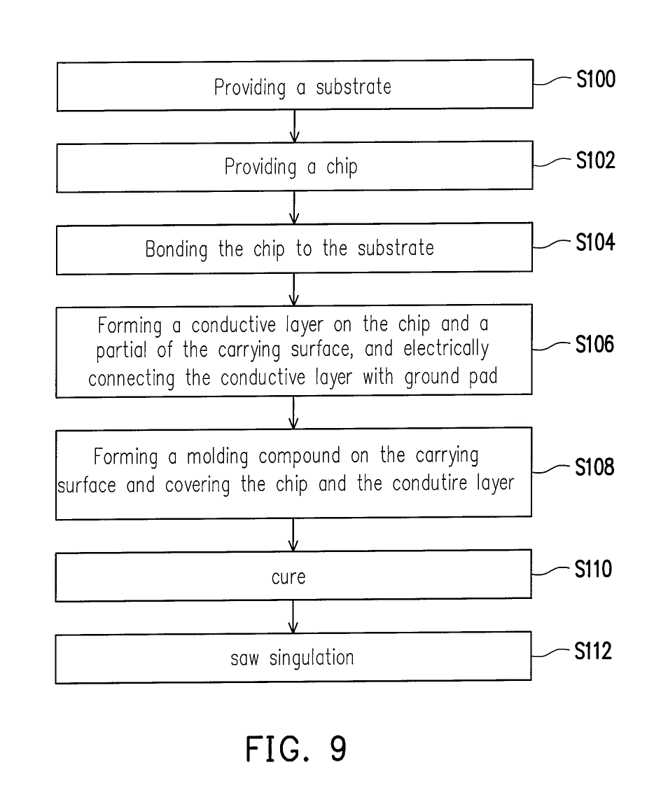

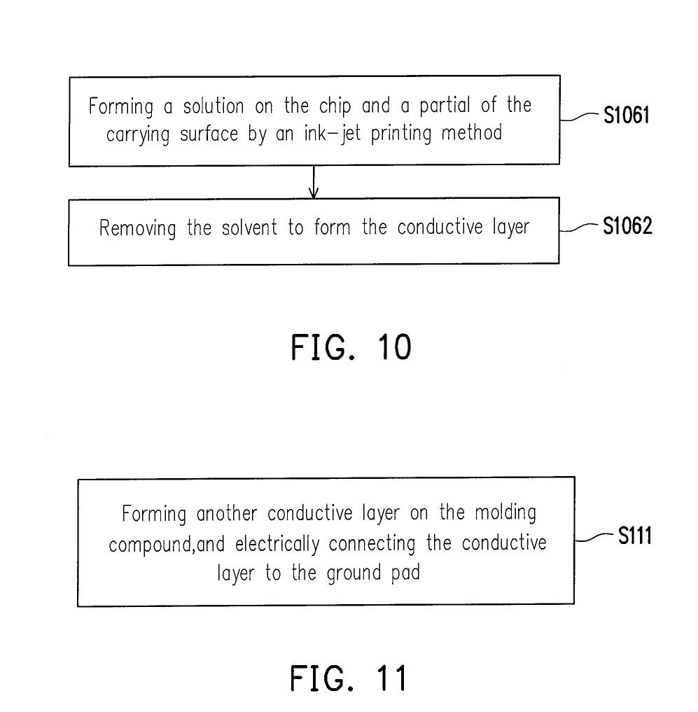

FIG. 1 to FIG. 4 illustrate a chip packaging process according to the first embodiment of the present invention. FIG. 5 to FIG. 8 show top view of FIG. 1 to FIG. 4 respectively. FIGS. 9 and 10 show a flow chart of the chip packaging process according to the first embodiment of the present invention.

First, a multi-chip package such as an SIP (System in Package) is taken as an example in the first embodiment. FIG. 1 corresponds to steps S100 and S102. In step S100, a substrate 200 is provided. The substrate 200 has a carrying surface 200a. The substrate 200 has at least one assembly area arranged in array which could be divided by saw lines 250, wherein two by three of them are shown as an example in FIG. 5. Within the assembly area, at least a ground pad 202, three for example (FIG. 5) are disposed on the carrying surface 200a. Vias 201 for electrically connecting the ground pads 202 are formed in the substrate 200. Within the assembly area, there are some electronic devices 204 disposed, such as passive components, on the carrying surface 200a, and also some connection pad 206 are formed on the substrate 200. In step S102, within the assembly area, at least one chip 208, three for example (FIG. 5) are provided. Each of the chips 208 has an active surface 208a and a back surface 208b opposite thereto. Bonding pads 210 are formed on the active surface 208a.

FIG. 2 and FIG. 6 correspond to step S104. In step S104, the chips 208 are bonded to the substrate 202 by facing the active surface 208a of the chip 208 towards the carrying surface 200a of the substrate 200, wherein the ground pads 202 are disposed outside of the chips 208 within the assembly area. The ground pads 202 are ring shaped surrounding the chips 208 respectively as shown in FIG. 5. The way bonding the chips 208 and the substrate 200 comprises disposing a plurality of conductive bumps 212 on the active surface 208a of the chips 208 and then to perform a reflow process in order to electrically connect the chips 208 and the substrate 200. After the chips 208 and the substrate 200 are bonded, an underfill 214 is disposed between the active surface 208a of the chips 208 and the carrying surface 200a of the substrate 200. The underfill 214 encapsulates the conductive bumps 212.

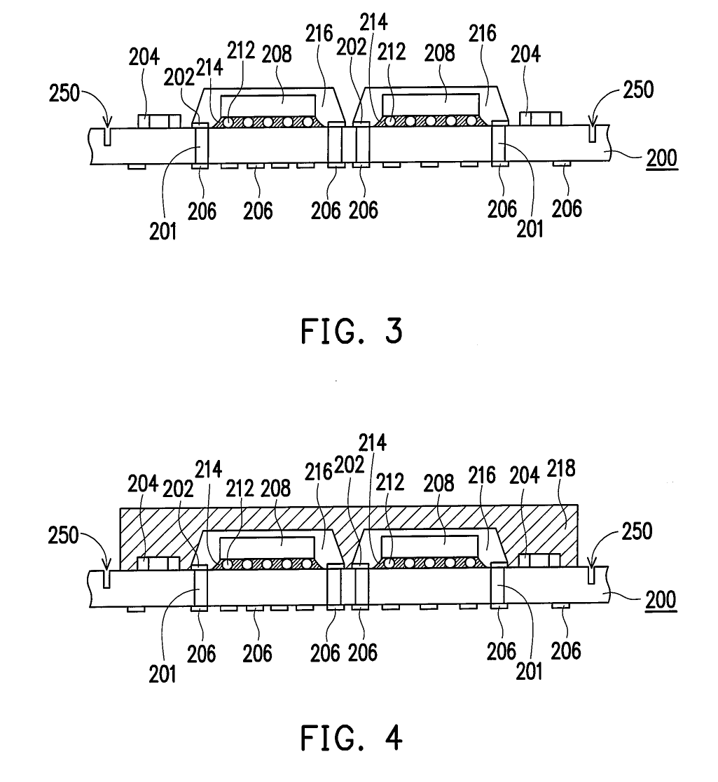

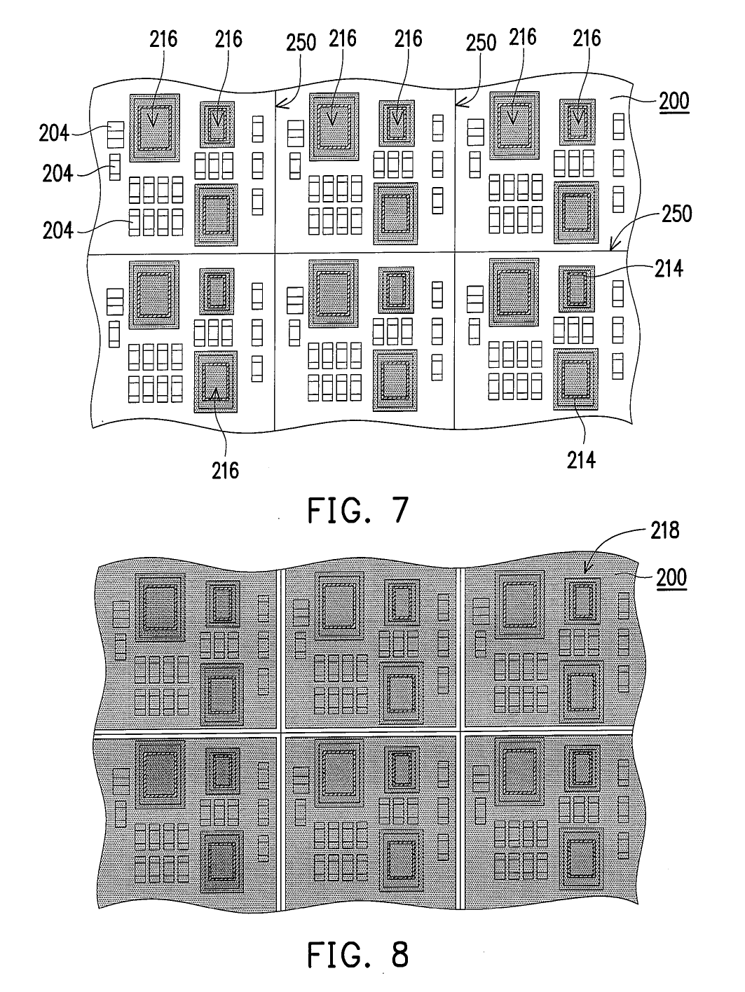

FIG. 3 and FIG. 7 correspond to step S106. In step S106, a conductive layer 216 is directly formed on the chips 208 and a portion of the carrying surface 200a to electrically connect to the ground pads 202 by ink-jet printing, plating, sputtering or spraying method, wherein the ink-jet printing method is preferable. The ground pads 202 can be electrically connected to the connection pads 206 through vias 201. By using the ink-jet printing method, a specific pattern can be directly printed. In FIG. 7, for easily understanding, shadow parts represent the conductive layer 216 and the chips 208 and underfill 214 under the conductive layer 216 visibly remain in purpose. Usually, where the place covered by the conductive layer 216 can not be seen. The ink-jet printing method for forming the conductive layer 216 comprises steps S1061 and S1062 shown in FIG. 10. In step S1061, a solution is formed on the chips 208 and a portion of the carrying surface 200a by an ink-jet printing method, wherein the solution includes a solvent, such as a ink or other volatile solvents, a conductive material comprising Ag, Cu or Ni, etc., and a non-conductive material for attaching the conductive material on the chips 208 and the carrying surface 200a. In step S1062, the solvent is removed by a curing step, such as a heating step to vaporize the solvent and remain the conductive material to form the conductive layer 216.

FIG. 4 and FIG. 8 correspond to steps S108 and S110. In step S108, a molding compound 218 is formed on the carrying surface 200a of the substrate 200 to encapsulate the chips 208, the conductive layer 216 and other electronic devices 204. In FIG. 8, for easily understanding, an allover shadow part represents the molding compound 218 and the conductive layer 216, chips 208 and underfill 214 under the molding compound 218 visibly remain in purpose. Usually, where the place covered by the molding compound 218 can not be seen. In step S110, a heating step, such as a cure step is performed to cure the molding compound 218.

After the molding compound 218 has been cured, in step S112, a saw singulation step is performed to cut the substrate 200 according the saw lines 250.

FIG. 11 shows a flow chart after a molding compound has been cured in the first embodiment. FIG. 12 shows a chip package formed by further performing step of FIG. 11 in a cross-sectional view.

Between steps S110 and S112, it can be further performed step S111 shown in FIG. 11. In step S111, another conductive layer 216′ is formed on the molding compound 218 and electrically connected to another ground pads 202′. The steps for forming the another conductive layer 216′ are similar to steps S1061 and S1062. In this case, another vias 201′ for electrically connecting the ground pads 202′ to the connection pads 206 should be formed in advance in the substrate 200. The another ground pads 202′ should be formed in advance on carrying surface 200a of the substrate 200 at an area outside of the molding compound 218.

### Second Embodiment

FIG. 13 illustrates a chip package according to the second embodiment of the present invention in a cross-sectional view.

The second embodiment differs from the first embodiment in that within the assembly area, each of the chips 208 are covered by one conductive layer 216 respectively in the first embodiment, while more than one chip 208 are covered by the same conductive layer 216 in the second embodiment. That is to say, the conductive layer can be formed according to the layout of the circuit, within the assembly area one chip can be covered by one conductive layer or more than one chip can be covered by the same conductive layer.

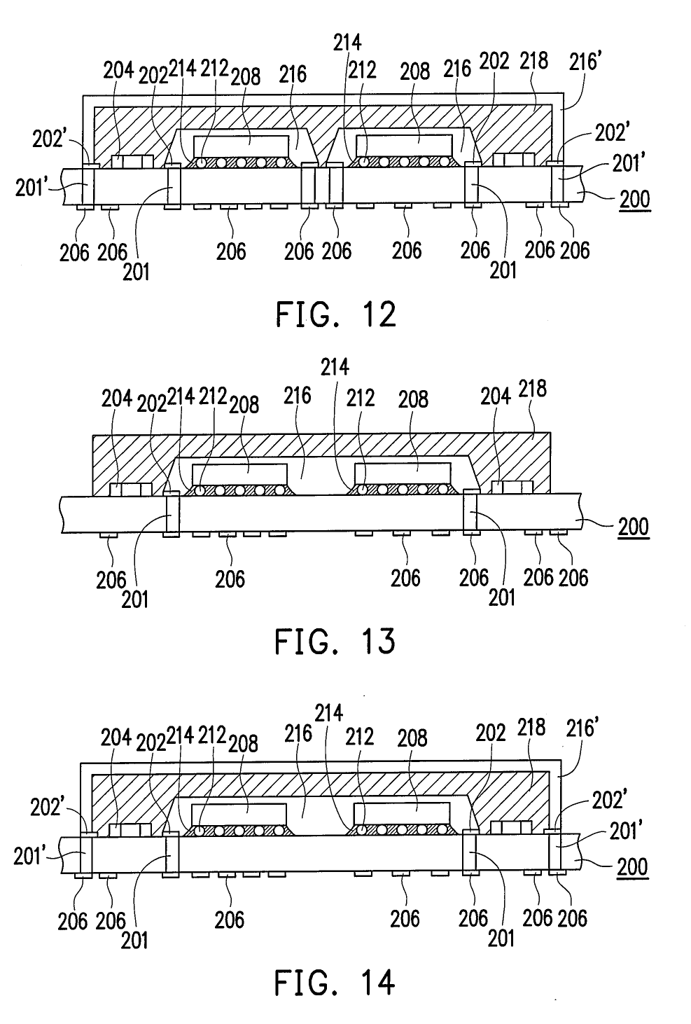

FIG. 14 illustrates a modification example of a chip package according to the second embodiment of the present invention in a cross-sectional view.

Another conductive layer 216′ is formed on the molding compound 218 of the second embodiment. The another conductive layer 216′ can be electrically connected to another ground pads 202′.

### Third Embodiment

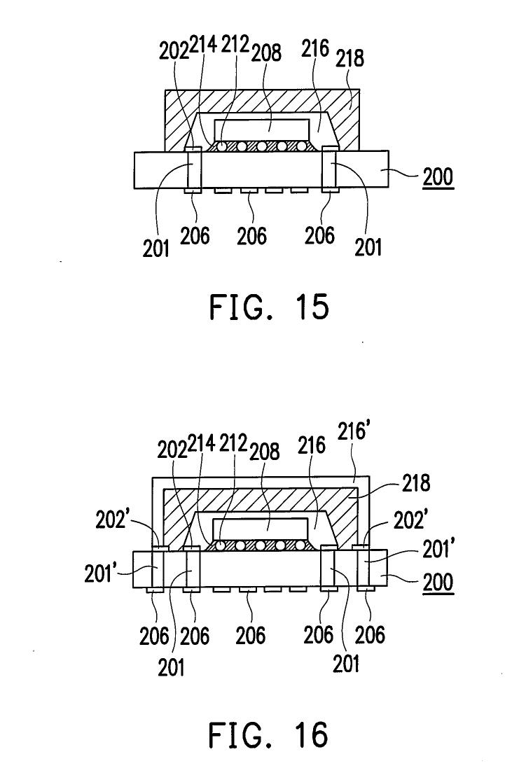

FIG. 15 illustrates a chip package according to the third embodiment of the present invention in a cross-sectional view.

The third embodiment differs from the first embodiment in that, a multi-chip package is taken as an example in the first embodiment, while a single-chip package is taken as an example in the third embodiment. The other electronic devices 204 are omitted in the third embodiment.

The chip package, comprises: a substrate 200, a chip 208, a conductive layer 216 and a molding compound 218. The conductive layer 216 is directly formed on the chip 208 and a portion of the carrying surface 200a to cover the chip 208 and a portion of the carrying surface 200a. The ground pad 202 is disposed outside of the chip 208. For example, the ground pad 202 is ring shaped surrounding the chip 208 as shown in FIG. 5.

FIG. 16 illustrates a modification example of a chip package according to the third embodiment of the present invention in a cross-sectional view.

Another conductive layer 216′ is formed on the molding compound 218 of the third embodiment. The another conductive layer 216′ can be electrically connected to another ground pads 202′.

According to the present invention, a conductive layer can be formed on the chip and be inside the molding compound to serve as a shield material. Another conductive layer can be formed on the molding compound serve as another shield material. In the case when using plating, spraying or sputtering method to form the conductive layer, it is necessary to form an overall conductive layer in advance and then to pattern the conductive layer into specific pattern. Alternatively, by using plating method, a photo-resist can be formed and patterned in advance to form a plurality of openings, and then a conductive layer can be plated in the openings of the photo-resist to form a specific pattern. However, by using spraying or sputtering method, the photo-resist cannot be formed in advance since it is difficult to remove the photo-resist if a metal layer is formed above the photo-resist. By using spraying or sputtering method, a photo-resist is formed above the overall conductive layer, and then the photo-resist is removed into a specific pattern, and then the conductive layer exposed by the photo-resist is removed into a specific pattern. However, by using the ink-printing method, the conductive layer made of a specific pattern can be printed directly without forming photo-resist, etching steps, . . . etc.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip packaging process, comprising:
providing a substrate, having a carrying surface and at least a ground pad disposed on the carrying surface;
providing a chip, having an active surface and a back surface opposite thereto;
bonding the chip to the substrate by facing the active surface of the chip towards the carrying surface of the substrate, wherein the ground pad is disposed outside of the chip;
forming a conductive layer on the chip and a portion of the carrying surface, and electrically connecting the conductive layer with the ground pad; and
forming a molding compound on the carrying surface of the substrate and encapsulating the chip and the conductive layer.

2. The chip packaging process according to claim 1, wherein bonding the chip and the substrate comprises disposing a plurality of conductive bumps on the active surface of the chip to electrically connect the chip and the substrate.

3. The chip packaging process according to claim 2, wherein bonding the chip and the substrate further comprises disposing an underfill between the active surface of the chip and the carrying surface of the substrate and encapsulating the conductive bumps with the underfill.

4. The chip packaging process according to claim 1, wherein forming the conductive layer comprises;
forming a solution on the chip and a portion of the carrying surface by an ink-jet printing method, wherein the solution includes a solvent and a conductive material; and
removing the solvent to form the conductive layer with the conductive material remained behind.

5. The chip packaging process according to claim 4, wherein the solvent is a volatile solvent.

6. The chip packaging process according to claim 4, wherein removing the solvent comprising a heating step to vaporize the solvent of the solution.

7. The chip packaging process according to claim 4, wherein the conductive material comprises Ag, Cu or Ni.

8. The chip packaging process according to claim 1, further comprising a heating step to cure the molding compound after the molding compound has been formed.

9. The chip packaging process according to claim 1, further comprising forming another conductive layer on the molding compound and electrically connecting the another conductive layer to another ground pad.

10. The chip package process according to claim 9, wherein the another ground pad is disposed on the carrying surface of the substrate and outside of the molding compound.

11. The chip packaging process according to claim 9, wherein forming the another conductive layer comprising:
forming a solution on the molding compound, wherein the solution includes a solvent and a conductive material; and
removing the solvent to form the conductive layer with the conductive material remained behind.

12. The chip packaging process according to claim 11, wherein the solvent is a volatile solvent.

13. The chip packaging process according to claim 11, wherein removing the solvent comprises a heating step to vaporize the solvent of the solution.

14. The chip packaging process according to claim 11, wherein the conductive material comprises Ag, Cu or Ni.
